(19) United States
(12) Patent Application Publication
(10) Pub. No.: US 2011/0009999 A1
(43) Pub. Date: Jan. 13, 2011

(54) PLASMA REACTOR WITH RF GENERATOR AND AUTOMATIC IMPEDANCE MATCH WITH MINIMUM REFLECTED POWER-SEEKING CONTROL

(75) Inventors: Chunlei Zhang, Santa Clara, CA (US); Lawrence Wong, Fremont, CA (US); Kartik Ramaswamy, San Jose, CA (US); James P. Cruse, Soquel, CA (US); Hiroji Hanawa, Sunnyvale, CA (US)

Correspondence Address: LAW OFFICE OF ROBERT M. WALLACE, 2112 EASTMAN AVENUE, SUITE 102, VENTURA, CA, 93003, US

(73) Assignee: Applied Materials, Inc., Santa Clara, CA (US)

(21) Appl. No.: 12/502,037

(22) Filed: Jul. 13, 2009

(51) Int. Cl. H01L 21/306; B05C 11/00; G06F 19/00

(52) U.S. Cl. 700/121; 118/708; 156/345.28

(57) ABSTRACT

An impedance match at an RF generator output of a plasma reactor includes plural minimum-seeking loop controllers having respective feedback input ports coupled to receive a reflected RF power signal from a reflected power sensing circuit and respective control output ports. The output ports are coupled to variable reactances of an impedance match circuit that is connected between the RF generator and an RF power applicator of the reactor.

### BACKGROUND

Processing of workpieces, such as semiconductor wafers, using an RF plasma requires that the output impedance of the RF generator be matched to the load impedance presented by the plasma and reactor chamber. The load impedance tends to vary during processing of the workpiece, due to fluctuations of the plasma in the reactor chamber. Fluctuations in load impedance create fluctuations in the RF power delivered to the plasma and RF power reflected back to the RF generator. As RF impedance mismatch increases, the amount of RF power that is reflected back to the RF generator increases, while the amount of RF power delivered to the plasma decreases. Such fluctuations change the plasma conditions and therefore affect the plasma processing of the workpiece, making it difficult to control process parameters, such as (for example) etch rate or deposition rate, etc. Therefore, in order to maintain process control, a plasma reactor typically employs a dynamic impedance match circuit connected between the RF generator and the RF power applicator of the reactor chamber. A dynamic impedance match circuit is employed because it is capable of responding to changes in the plasma load impedance that would otherwise create an unacceptably large impedance mismatch. A dynamic impedance match circuit responds to changes in measured reflected RF power by changing reactances of various reactive components constituting the RF match circuit in such a manner as to minimize the amount of RF power reflected back to the RF generator. These changes are determined by a complex gradient-based algorithm involving gradient searching. Such an algorithm responds to sensed reflected RF power at the RF generator as a feedback control signal to govern the impedance match circuit.

The RF power applicator may be an electrode or a coil antenna, for example. The electrode may be at the reactor chamber ceiling or may be an internal electrode within a workpiece support, or the electrode may be any other part or wall of the reactor chamber. There may be plural RF power applicators of the reactor chamber, with different RF generators of different frequencies coupled to different ones of the RF power applicators through individual dynamic impedance matches.

One problem with dynamic impedance matches is that the gradient-based algorithms they employ must be sufficiently robust to provide optimal control for all of the variable reactive elements of the impedance match circuit that are to be controlled. Such algorithms are necessarily complex, and require a significant amount of time to respond to fluctuations in load impedance. During the time required for the algorithm to respond to a given change in load impedance, the delivered power and plasma conditions may fluctuate in an uncontrolled manner, resulting in at least a slight variation in process conditions (e.g., process rate) from the desired ones. In the past, such temporary variations were acceptable because the variations in process rate were small. However, as device sizes have now been miniaturized to a much greater degree than in the past, it has become more critical to restrict process variations to extremely small amounts. This requires a much faster response that conventional dynamic impedance match circuits are incapable of providing.

### SUMMARY

An impedance match is provided in a plasma reactor system including a reactor chamber having process gas injection apparatus, an RF power applicator and an RF power generator. The impedance match includes an impedance match circuit coupled between the RF power generator and the RF power applicator, the impedance match circuit including plural reactive elements arrayed in a circuit topology. A reflected power sensing circuit is coupled to the RF power generator. The impedance match further includes plural minimum-seeking loop controllers having respective feedback input ports coupled to receive a reflected RF power signal from the reflected power sensing circuit and respective control output ports coupled to govern reactances of respective ones of the reactive elements. Each one of the plural minimum-seeking loop controllers includes a source of a predetermined time-varying signal, a first transformer for transforming the reflected RF power signal to a transformed reflected RF power signal, a combiner for combining the predetermined time-varying signal with the transformed reflected RF power signal to produce a combined signal, a second transformer for transforming the combined signal to produce a transformed combined signal, and an integrator for integrating the transformed combined signal to produce an output signal to the respective output port.

In one embodiment, each minimum-seeking loop controller is a perturbation-based minimum-seeking controller in which the predetermined time-varying signal is a sine wave signal α[sin(ωt)], the first transformer is a high pass filter; the combiner is a multiplier, the second transformer is a low pass filter, and the integrator provides an integration over time.

In another embodiment, each minimum-seeking loop controller is a sliding scale-based minimum-seeking loop controller, in which the predetermined time-varying signal is a time-increasing ramp signal g(t), the first transformer performs a sign reversal of the reflected RF power signal, the combiner comprises an adder, the second transformer computes a periodic switching function that depends upon the output of the combiner, and the integrator performs an integration over time. This embodiment may include a match criteria processor that hold the loop controller output at its latest value whenever a sufficient impedance match is attained.

### BRIEF DESCRIPTION OF THE DRAWINGS

So that the manner in which the exemplary embodiments of the present invention are attained and can be understood in detail, a more particular description of the invention, briefly summarized above, may be had by reference to the embodiments thereof which are illustrated in the appended drawings. It is to be appreciated that certain well known processes are not discussed herein in order to not obscure the invention.

FIG. 1 is a schematic block diagram depicting an RF source power impedance match in a plasma reactor in accordance with an embodiment.

FIG. 2 is a schematic block diagram depicting an RF bias power impedance match in a plasma reactor in accordance with an embodiment.

FIG. 3 is a schematic block diagram depicting an individual perturbation-based controller that is employed in each one of plural loops of the impedance match in accordance with a first embodiment.

FIG. 4 is a schematic block diagram depicting an individual sliding scale-based controller that is employed in each one of plural loops of the impedance match in accordance with a second embodiment.

FIG. 5 is a graph depicting a sliding scale ramp function employed by the controller of FIG. 4.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

An extremely fast minimum-seeking impedance match controller is employed that responds quickly to fluctuations in load impedance. The minimum-seeking impedance match controller is much simpler and faster than conventional gradient-based controllers, and yet is capable of simultaneously controlling any number of variable reactances included in the impedance match circuit.

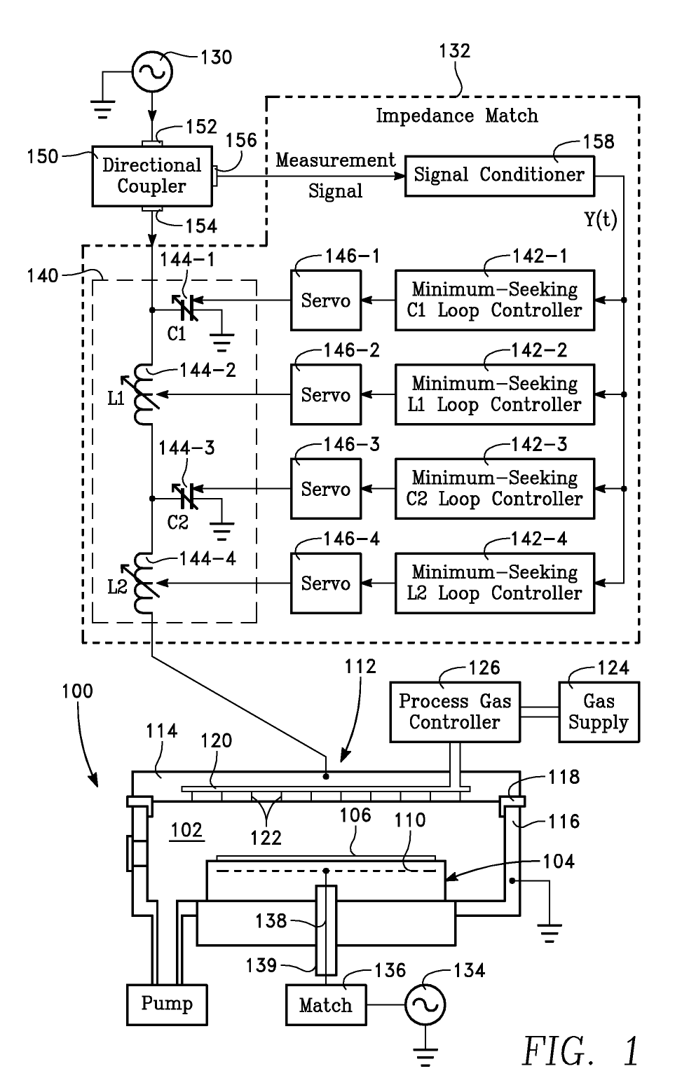

Referring to FIG. 1, a plasma reactor 100 includes a vacuum chamber 102 enclosing a workpiece support 104 on which a workpiece 106 may be held during processing. The reactor 100 may have different RF power applicators, such as an internal electrode 110 within the workpiece support 104 and an RF source power applicator 112. The RF source power applicator 112 may be a coil antenna, although it is depicted in FIG. 1 as a ceiling electrode 114 of the chamber 102. For example, the ceiling electrode 114 may be insulated from a grounded chamber side wall 116 by an insulator 118. The ceiling electrode 114 may function as a gas distribution plate and include an internal gas manifold 120 coupled to an array of gas injection orifices 122 in the bottom surface of the ceiling electrode 114, and supplied with process gas from a process gas supply 124 through a process gas controller 126.

Plasma RF source power is furnished by an RF source power generator 130 through a minimum-seeking impedance match 132 to the RF power applicator 112. Plasma RF bias power may be furnished by an RF bias power generator 134 through a bias impedance match 136 to the internal workpiece support electrode 110. The bias impedance match 136 may be connected to the electrode 110 through a center conductor 138 of a coaxial RF feed 139.

The minimum-seeking impedance match 132 includes an impedance match circuit 140 and plural minimum-seeking loop controllers 142-1, 142-2, 142-3, 142-4. The impedance match circuit 140 includes plural reactive elements (capacitors and inductors) including variable reactive elements 144-1, 144-2, 144-3, 144-4, which may be coupled together in any suitable topology, such as (for example) a pi-circuit as depicted in FIG. 1. Some of the variable reactive elements (e.g., the reactive elements 144-1 and 144-3) may be variable capacitors, while others of the variable reactive elements (e.g., the reactive elements 144-2 and 144-4) may be variable inductors. Not all of the reactive elements in the impedance match circuit 140 are necessarily variable. As indicated in FIG. 1, each of the variable reactive elements 144-1 through 144-4 is controlled by a corresponding one of the loop controllers 142-1 through 142-4. Optionally, the minimum-seeking loop controllers 142-1 through 142-4 may have their outputs coupled to respective servo mechanisms 146-1 through 146-4. The servo mechanisms 146-1 through 146-4 are mechanically linked to the corresponding variable reactive elements 144-1 through 144-4.

The minimum-seeking impedance match 132 senses the level of RF power reflected backward from the source power applicator 112 toward the RF generator 130. This sensing may be performed by a directional coupler 150 or other conventional device capable of sampling reflected RF power. The directional coupler 150 has a power input port 152 and a power output port 154, and introduces minimum insertion loss between the power ports 152, 154. The power ports 152, 154 are connected in series between the RF generator 130 and the impedance match circuit 140. In addition, the directional coupler 150 has a reflected power indicator port 156 providing a measurement signal indicative of the magnitude of reflected RF power traveling back toward the RF generator 130. The measurement signal from the reflected power indicator port 156 is coupled through an optional signal conditioner 158 to inputs of the minimum-seeking loop controllers 142-1 through 142-4. In one embodiment, the reflected power indicator port 156 was provided as an integral part of the RF generator 130 using internal RF voltage and current sensor apparatus within the RF generator 150, eliminating the need for the separate directional coupler 150.

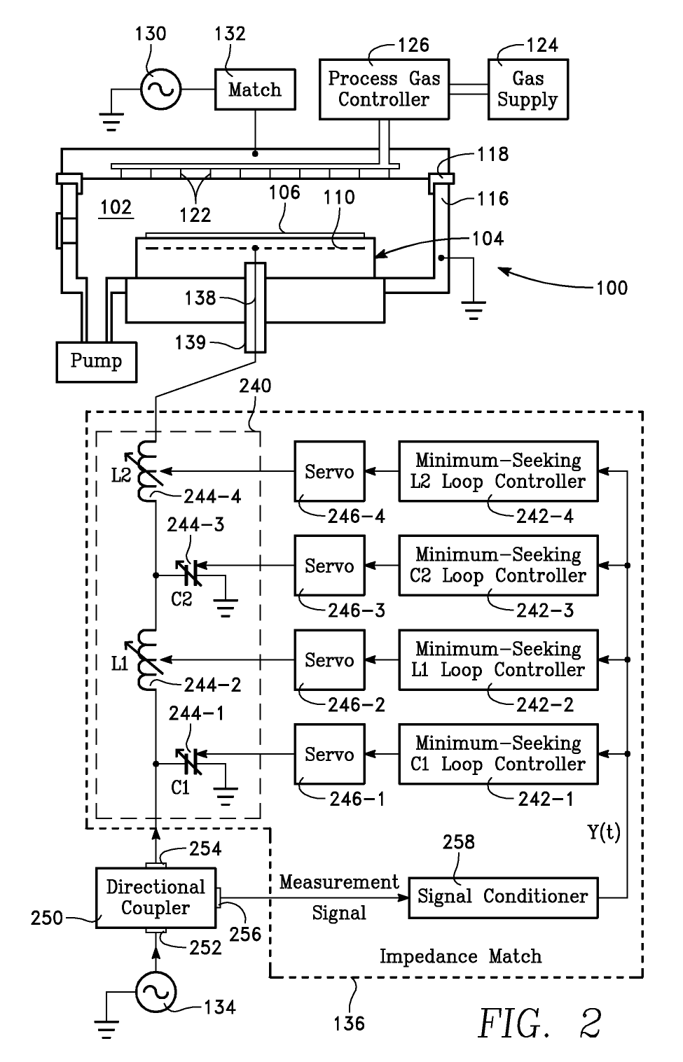

FIG. 2 depicts an embodiment in which the bias impedance match 136 is a minimum-seeking bias impedance match of a structure corresponding to that of the minimum-seeking source impedance match 132 of FIG. 1.

The minimum-seeking bias impedance match 136 includes an impedance match circuit 240 and plural minimum-seeking loop controllers 242-1, 242-2, 242-3, 242-4 etc. The impedance match circuit 240 includes plural reactive elements (capacitors and inductors) including variable reactive elements 244-1, 244-2, 244-3, 244-4, etc., which may be coupled together in any suitable topology, such as (for example) a pi-circuit as depicted in FIG. 2. Some of the variable reactive elements (e.g., the reactive elements 244-1 and 244-3) may be variable capacitors, while others of the variable reactive elements (e.g., the reactive elements 244-2 and 244-4) may be variable inductors. Not all of the reactive elements in the impedance match circuit 240 are necessarily variable. As indicated in FIG. 2, each of the variable reactive elements 244-1 through 244-4 is controlled by a corresponding one of the loop controllers 242-1 through 242-4. Optionally, the minimum-seeking loop controllers 242-1 through 242-4 may have their outputs coupled to respective servo mechanisms 246-1 through 246-4 mechanically linked to the corresponding variable reactive elements 244-1 through 244-4.

The minimum-seeking impedance match 136 senses the level of RF power reflected back toward the RF generator 134 by a directional coupler 250 or other conventional device capable of sampling reflected RF power. The directional coupler 250 has a power input port 252 and a power output port 254, and introduces minimum insertion loss between the power ports 252, 254. The power ports 252, 254 are connected in series between the RF generator 134 and the impedance match circuit 240. In addition, the directional coupler 250 has a reflected power indicator port 256 providing a measurement signal indicative of the reflected RF power traveling back toward the RF generator 134. The measurement signal from the reflected power indicator port 256 is coupled through an optional signal conditioner 258 to inputs of each of the minimum-seeking loop controllers 242-1 through 242-4.

Each of the loop controllers 142-1 through 142-4 of FIG. 1 or the loop controllers 242-1 through 242-4 of FIG. 2 may be identical in structure, but operate independently.

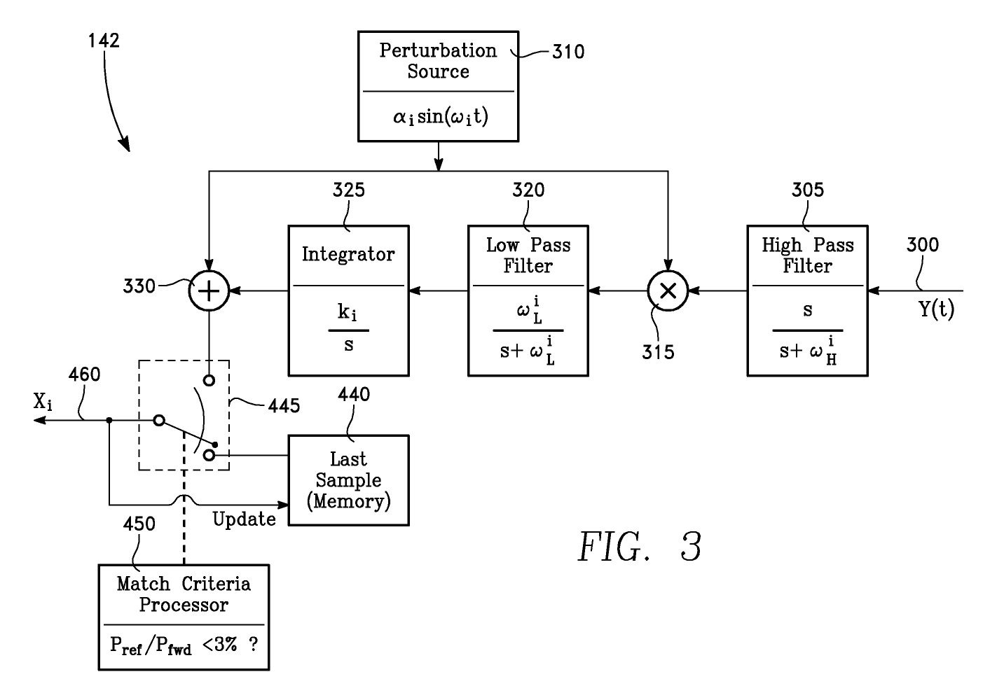

In accordance with a first embodiment, each loop controller is configured to perform a perturbation-based minimum-seeking algorithm. A typical one of the four loop controllers 142-1 through 142-4 is depicted in FIG. 3 in accordance with a first embodiment. (The loop controller 142 depicted in FIG. 3 is also typical of each of the loop controllers 242-1 through 242-4 of FIG. 2.) The loop controller 142 of FIG. 3 has an input 300 coupled to the signal conditioner 158 (FIG. 1) to receive the reflected power measurement signal from the signal conditioner 158 (FIG. 1). The reflected power measurement signal varies over time and is labeled FIG. 3 as a time dependent function Y(t). The loop controller 142 of FIG. 3 further includes a high pass filter 305 that filters the signal Y(t) at the input port 300 in accordance with a high pass filter response defined by the Laplace transform s/[s+ω_{H}ⁱ] where the angular frequency ω_{H}ⁱ is selected empirically and may be on the order of about 1 radian per second, in one example. The index “i” denotes the particular one of the four loop controllers 142-1 through 142-4 in which ω_{H}ⁱ is used. For example, i=2 for the loop controller 142-2. The function of the high pass filter 305 may be viewed as one of removing a D.C. component from the incoming reflected power signal Y(t). A perturbation source 310 provides a periodic perturbation signal defined by αᵢ[sin(ωᵢt)]. Again, the index “i” refers to the particular loop controller. In one example, αᵢ is on the order of about 0.5 and ωᵢ is on the order of about 20 or 30 radians per second. Although in the present embodiment, the factor αᵢ is a constant, in other embodiments it may be implemented as a time-varying function. Moreover, the “sin” function of the perturbation signal αᵢ[sin(ωᵢt)] may be changed to a square wave function or a sawtooth function or other periodic function. A multiplier 315 multiplies the output of the high pass filter 305 (i.e., the non-D.C. component of Y(t)) by the perturbation signal. The product produced by the multiplier 315 is one of two different sinusoids, namely Y(t) and αᵢ[sin(ωᵢt)]. The resulting product is processed through an optional low pass filter 320 having a low pass filter response defined by the Laplace transform ω_{L}ⁱ/[s+ω_{L}ⁱ], where ω_{L}ⁱ may have a value which is selected empirically and may be from on the order of 1 to 50 radians per second. As before, the index “i” refers to the particular one of the four loop controllers 142-1 through 142-4. The output of the low pass filter 320 may be regarded as a function behaving similarly to the derivative of the reflected power Y(t) with respect to the loop controller output. An integrator 325 integrates over time the output of the low pass filter 320, the integrator 325 corresponding to the Laplace transform kᵢ/s, where kᵢ is determined empirically and may have a value of about 1. An adder 330 adds the output of the perturbation source 310 to the output of the integrator 325. The output of the adder 330 is the final computation. A match criteria processor 450 governing a switch 445 determines whether a sufficient impedance match has been attained in accordance with a predetermined criteria. This criteria, for example, may be satisfied by a determination of whether the reflected power Y(t) is less than 3% of the total power, for example. A threshold other than 3% may be employed. If the criteria is not currently met, then the output of the adder 330 is continuously applied through the switch 445 to output 460 of the loop controller as the loop controller output signal xᵢ. This output signal is also applied as an update to a previous sample memory 440. Otherwise, if the match criteria processor 450 finds that a nearly ideal impedance match has been achieved (e.g., reflected power Y(t) less than some threshold such as 3% of total power), then the current value of the loop controller output xᵢ is stored in the memory 440, updating of the memory 440 is stopped, and the contents of the memory 440 is applied through the switch 445 as a constant value to the loop controller output 460, until such time as the match criteria is no longer met. The signal at the output 460 may be labeled xᵢ, and is the command to the i^{th} one of the servo mechanisms 146-1 through 146-4 (FIG. 1) to set the reactance of the corresponding variable reactance element 144-1 through 144-4 (FIG. 1).

The phase relation between two sinusoids Y(t) and αᵢ[sin(ωᵢt)] multiplied by the multiplier 315 is affected by whether the loop controller output xᵢ is above or below a value at which the reflected power Y(t) is minimum. The output of the low pass filter 320 may be viewed as a low frequency or D.C. component of the product of the two sinusoids. This low frequency component (the output of the filter 320), and may be regarded as a function behaving similarly to the derivative of the reflected power Y(t) with respect to the loop controller output xᵢ. The output of the integrator 325 may be regarded as a gradient update based upon this derivative.

As described above, each of the loop controllers 142-1 through 142-4 may be of the same structure, but they are each physically separate from one another and operate independently. Thus, the high pass filter frequency ω_{H}ⁱ, the low pass filter frequency ω_{L}ⁱ, the perturbation signal frequency ωᵢ and the output xᵢ of one loop controller (i.e., the i^{th} one of the four loop controllers 142-1 through 142-4) differs from that of the other loop controllers.

There are some constraints on the selections of the parameters for each loop controller. Specifically, αᵢ, ωᵢ, ω_{H}ⁱ, ω_{L}ⁱ and kᵢ are each positive real numbers. Also, the perturbation source frequency ωᵢ should be different in each different loop controller, and should not be harmonically related to the perturbation source frequency of any other loop controller.

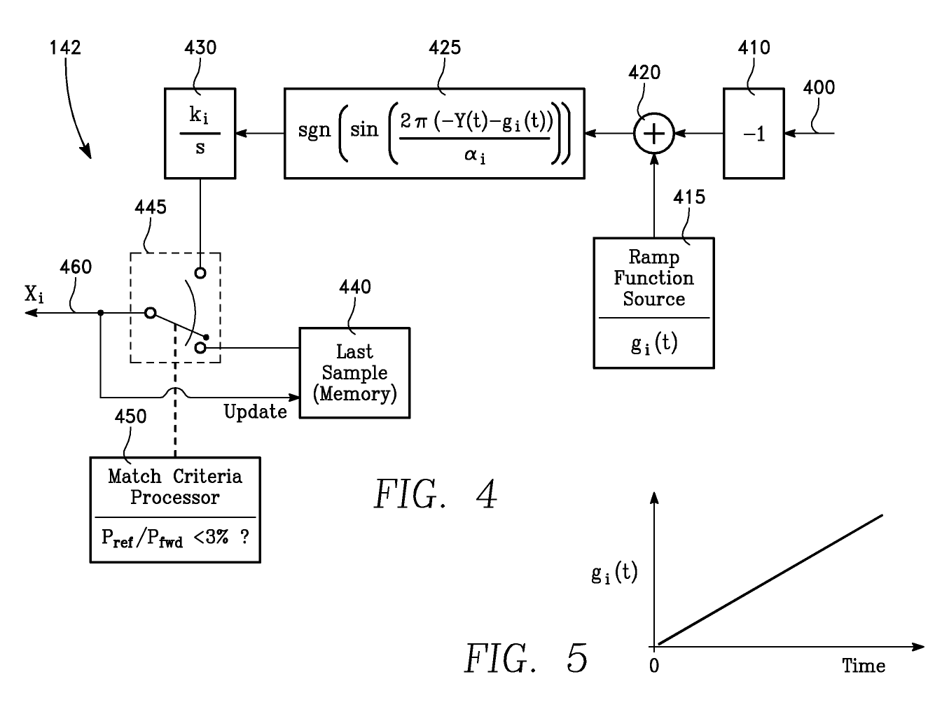

In accordance with a second embodiment, each of the loop controllers 142-1 through 142-4 is configured to perform a sliding scale-based minimum-seeking algorithm. A typical loop controller 142 in accordance with this second embodiment is depicted in FIG. 4. The loop controller 142 of FIG. 4 has an input 400 coupled to the signal conditioner 158 (FIG. 1) to receive the reflected power measurement signal Y(t) from the signal conditioner 158 (FIG. 1). The loop controller 142 of this second embodiment (FIG. 4) further includes a multiplier 410 that reverses the sign of the signal Y(t) at the input port 400. A ramp function source 415 provides a function gᵢ(t) that increases monotonically over time. As noted previously, the index “i” denotes the particular one of the four loop controllers 142-1 through 142-4 of FIG. 1 (or 242-2 through 242-4 of FIG. 2) using the parameter. An adder 420 adds the output of the multiplier 410 to the output of the ramp function source 415 to produce a function −Y(t)−gᵢ(t). An operator 425 computes the function sgn{sin{2π[−Y(t)−gᵢ(t)]/αᵢ}}. The function “sgn” is +1 if the argument, {sin{2π[−Y(t)−gᵢ(t)]/αᵢ}, is positive and is −1 if the argument is negative, or zero if the argument is zero. The output of the operator 425, sgn{sin{2π[−Y(t)−gᵢ(t)]/αᵢ}}, is a periodic switching function of the sum of Y(t) and gᵢ(t). An integrator 430, denoted by the Laplacian transform kᵢ/s in FIG. 4, computes the integral over time of the output of the operator 425, namely the switching function sgn{sin{2π[−Y(t)−g(t)]/α}}, and provides the result as the control output xᵢ. FIG. 5 is a graph illustrating one example of the sliding scale function g(t). The loop controller of FIG. 4 forces the reflected power Y(t) continually decrease as a function of the rate of increase of the sliding scale function gᵢ(t), so that Y(t) continually decreases toward a minimum value.

A match criteria processor 450 governing a switch 445 determines whether a sufficient impedance match has been attained in accordance with a predetermined criteria. This criteria, for example, may be satisfied by a determination of whether the reflected power Y(t) is less than 3% of the total power, for example. A threshold other than 3% may be employed. If the criteria is not currently met, then the output of the integrator 430 is continuously applied through the switch 445 to output 460 of the loop processor 142 as the loop controller output signal xᵢ. This output signal is also applied as an update to a previous sample memory 440. Otherwise, if the match criteria processor 450 finds that a nearly ideal impedance match has been achieved (e.g., reflected power Y(t) less than some threshold such as 3% of total power), then the current value of the loop controller output xᵢ is stored in a memory 440, updating of the memory 440 is stopped, and the contents of the memory 440 is applied through the switch 445 as a constant value to the loop controller output 460.

The values of kᵢ and αᵢ are real positive numbers that may be determined empirically and may be on the order of about 1 or 10, for example. The slope d/dt(gᵢ(t)) of the sliding scale function gᵢ(t) is selected empirically in accordance with a desired rate of convergence of the loop controller and may be on the order of 0.5, for example. Each of the loop controllers operates independently, and its parameters, kᵢ, αᵢ and d/dt(gᵢ(t)) and output xᵢ are different from those of the other loop controllers.

The loop controllers 142-1 through 142-4 of FIG. 1 or 242-1 through 242-4 of FIG. 2 may be implemented as analog circuit or as digital circuits or as a programmed microprocessor or microprocessors.

An advantage of the extremum seeking control described above is that the calculation of the gradient is performed by two filters, and is therefore inherently fast and accurate. In contrast, traditional approaches require a measurement of the gradient or a numerical calculation of the gradient using finite differences, requiring more computations and resulting in inferior accuracy.

While the foregoing is directed to embodiments of the present invention, other and further embodiments of the invention may be devised without departing from the basic scope thereof, and the scope thereof is determined by the claims that follow.

What is claimed is:

1. A plasma reactor system comprising a reactor chamber having process gas injection apparatus, an RF power applicator and an RF power generator and an impedance match, wherein said impedance match comprises:
an impedance match circuit coupled between said RF power generator and said RF power applicator, said impedance match circuit comprising plural reactive elements arrayed in a circuit topology;
a reflected power sensing circuit coupled to said RF power generator; and
plural minimum-seeking loop controllers having respective feedback input ports coupled to receive a reflected RF power signal from said reflected power sensing circuit and respective control output ports coupled to govern reactances of respective ones of said reactive elements.

2. The plasma reactor system of claim 1 wherein each one of said plural minimum-seeking loop controllers comprises:
a source of a predetermined time-varying signal;
a first transformer for transforming said reflected RF power signal to a transformed reflected RF power signal;
a combiner for combining said predetermined time-varying signal with said transformed reflected RF power signal to produce a combined signal;
a second transformer for transforming said combined signal to produce a transformed combined signal; and
an integrator for integrating said transformed combined signal to produce an output signal to the respective output port.

3. The plasma reactor system of claim 2 wherein said one minimum-seeking loop controller is a perturbation-based minimum-seeking controller and wherein:
said predetermined time-varying signal is a sine wave signal α[sin(ωt)];
said first transformer comprises a high pass filter;
said combiner comprises a multiplier;
said second transformer comprises a low pass filter; and
said integrator provides an integration over time.

4. The plasma reactor system of claim 3 wherein:
said high pass filter corresponds to a Laplace transform s/[s+ω_{H}];
said low pass filter corresponds to a Laplace transform ω_{L}/[s+ω_{L}]; and
said integrator corresponds to a Laplace transform k/s.

5. The plasma reactor system of claim 3 further comprising:
an adder having one input coupled to an output of said integrator and another input coupled to said source of said predetermined time-varying signal, said adder providing a sum output to said output port.

6. The plasma reactor system of claim 2 wherein said one minimum-seeking loop controller is a sliding scale-based minimum-seeking loop controller, and wherein:
said predetermined time-varying signal is a time-increasing ramp signal g(t);
said first transformer performs a sign reversal of said reflected RF power signal;
said combiner comprises an adder;
said second transformer computes a periodic switching function that depends upon the output of said combiner; and
said integrator performs an integration over time.

7. The plasma reactor system of claim 6 wherein said reflected RF power signal is Y(t) and said period switching function is sgn{sin{2π[−Y(t)−g(t)]/α}}.

8. The plasma reactor system of claim 6 further comprising:
a match criteria processor responsive to said reflected RF power signal;
a memory storing a current value of the output signal of said one loop controller; and
said match criteria processor being adapted to substitute the contents of said memory for the output signal of said one loop controller whenever said reflected RF power signal indicates a predetermined impedance match threshold has been met.

9. The plasma reactor system of claim 8 wherein said predetermined impedance match criteria corresponds to a reflected RF power level less than a certain proportion of total power or forward power.

10. The plasma reactor system of claim 9 wherein said certain proportion is 3%.

11. In a plasma reactor comprising a reactor chamber having process gas injection apparatus, an RF power applicator and an RF power generator, an impedance match circuit coupled between said RF power generator and said RF power applicator, said impedance match circuit comprising plural reactive elements arrayed in a circuit topology, and a reflected power sensing circuit coupled to said RF power generator, a method of governing individual ones of said plural reactive elements to minimize reflected RF power, said method comprising:
generating a predetermined time-varying signal;
first transforming said reflected RF power signal to a transformed reflected RF power signal;
combining said predetermined time-varying signal with said transformed reflected RF power signal to produce a combined signal;
second transforming said combined signal to produce a transformed combined signal; and
integrating said transformed combined signal to produce an output signal and varying the impedance of the respective individual one of said reactive elements in accordance with said output signal.

12. The method of claim 11 wherein:
said predetermined time-varying signal is a sine wave signal α[sin(ωt)];
said first transforming comprises high pass filtering said reflected RF power signal;
said combining comprises a multiplying said transformed reflected RF power signal and said predetermined time-varying signal;
said second transforming comprises a low pass filtering said combined signal; and
said integrating comprises performing an integration over time.

13. The method of claim 12 wherein:
said high pass filtering corresponds to a Laplace transform s/[s+ω_{H}];
said low pass filtering corresponds to a Laplace transform ω_{L}/[s+ω_{L}]; and
said integrating corresponds to a Laplace transform k/s.

14. The method of claim 12 further comprising:
modifying said output signal by adding to it said predetermined time-varying signal, whereby said respective reactance is governed in accordance with the modified output signal.

15. The method of claim 11 wherein:
said predetermined time-varying signal is a time-increasing ramp signal g(t);
said first transforming comprises performs a sign reversal of said reflected RF power signal;
said combining comprises adding said transformed reflected RF power signal and said predetermined time-varying signal;
said second transforming comprises computing a periodic switching function that depends upon said combined signal produced by said combining; and
said integrating comprises performing an integration over time of said periodic switching function.

16. The method of claim 15 wherein said reflected RF power signal is Y(t) and said period switching function is sgn{sin{2π[−Y(t)−g(t)]/α}}.

17. The method of claim 15 further comprising:
storing in memory a current value of the output signal;
substituting the contents of said memory for the output signal whenever said reflected RF power signal indicates a predetermined impedance match threshold has been met.

18. The method of claim 17 wherein said predetermined impedance match criteria corresponds to a reflected RF power level less than a certain proportion of total power or forward power.

19. The method of claim 18 wherein said certain proportion is 3%.
